(19) United States
(12) Patent Application Publication
(10) Pub. No.: US 2007/0145436 A1
(43) Pub. Date: Jun. 28, 2007

(54) Thin film transistor substrate of liquid crystal display and method for fabricating same

(75) Inventor: Yao-Nan Lin, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/645,434

(22) Filed: Dec. 26, 2006

(30) Foreign Application Priority Data
Dec. 23, 2005 (TW) 94146294

(51) Int. Cl. H01L 29/76

(52) U.S. Cl. 257/288

(57) ABSTRACT

An exemplary thin film transistor substrate (200) includes a substrate (201), a gate (212), a gate insulating layer (203), an amorphous silicon layer (214), a pixel electrode (216), a drain (217), and a source (218). The gate is formed at the gate. The gate insulating layer is formed at the gate. The amorphous silicon layer is formed at the gate insulating layer. The transparent conductive layer is formed at the amorphous silicon layer. The pixel electrode is formed at the amorphous silicon layer. The drain is formed at the pixel electrode. The source is formed at the transparent conductive layer.

### FIELD OF THE INVENTION

The present invention relates to thin film transistor substrates of liquid crystal displays, and more particularly to a thin film transistor substrate of a liquid crystal display configured to provide a simple fabricating process for thereof.

### BACKGROUND

A typical liquid crystal display generally includes a substrate having a plurality of thin film transistors, a substrate having a plurality of color filters, and a liquid crystal layer interposed therebetween. The thin film transistor substrate includes a plurality of pixel regions. Each region has a pixel electrode and a thin film transistor designated as a switch for controlling a voltage of the pixel electrode and determining a volume of passing light, and the color filter arranged thereon provides chromatic fashion.

Referring to FIG. 13, this shows a cross-sectional view of a part of a conventional thin film transistor substrate 100 of a liquid crystal display. The thin film transistor 100 includes a substrate 101, a gate 102, a gate insulating layer 103, and a semiconductor layer 104, a source 105, a drain 106, a passivation layer 107, and a pixel electrode 108.

The gate 102 is disposed on the substrate 101. The gate insulating layer 103 made from silicon nitride is disposed on the gate 102 and the first substrate 101. The semiconductor layer 104 made from doped amorphous silicon is disposed on the gate insulating layer 103 above the gate 102. The source 105 and the drain 106 both are made from molybdenum, chromium, or aluminum, and are essentially symmetrically opposite to each other, above two sides of the semiconductor layer 104 respectively. The source 105 and the drain 106 are insulated from each other. The passivation layer 107 is disposed on the source 105, the drain 106, the semiconductor layer 104, and the gate insulating layer 103. After that, the pixel electrode 108 is disposed on the passivation layer 107. The pixel electrode 108 is connected to the drain 106 via a through hole (not labeled).

Referring to FIG. 14, this shows a-flow chart of steps of fabricating the thin film transistor substrate 100.

A first photo-mask process is described as follows.

In step S10, a first metal layer is patterned to from a gate formed.

The substrate 101 made from insulating material, such as, glass, quartz or porcelain, is provided. A first metal layer is deposited on the substrate 101, after that, and a first photoresist layer is deposited on the first metal layer.

In step S11, a gate is formed.

A first photo-mask is arranged above the first photoresist layer. An ultraviolet (UV) ray light source is used for developing the first photoresist layer with the first photo-mask to form a pattern for a gate. The first metal layer is etched to form the gate 102. Afterward, the first photoresist layer is removed.

In step S12, a gate insulating layer and an amorphous silicon layer is formed.

The gate insulating layer 103 is formed by chemical vapor deposition using silicon nitride with a reaction gas, such as, SiH4, NH3 on the substrate 101 and the gate 102. Then, an amorphous silicon layer is formed by chemical vapor deposition on the gate insulating layer 302. A second photoresist layer is deposited on the doped amorphous silicon layer.

A second photo-mask process is described as follows.

In step S13, a semiconductor layer is formed.

A second photo-mask is arranged above the second photoresist layer. An ultraviolet (UV) ray light source is used for developing the second photoresist layer with the second photo-mask to form a desired pattern on the amorphous silicon layer, and then, the amorphous silicon layer is etched to form a semiconductor layer 104. Afterward, the second photoresist layer is removed.

In step S14, a second metal layer is formed.

A second metal layer for a source and a drain is disposed on the substrate 101, and the semiconductor layer 104. A third photoresist layer is deposited on the second metal layer.

A third photo-mask process is described as follows.

In step S15, a source and a drain is formed.

A third photo-mask is arranged above the third photoresist layer. An ultraviolet (UV) ray light source is used for developing the third photoresist layer with the third photo-mask to form a desired pattern on the second metal layer, and then, the second metal layer is etched to independently form the source 105 and the drain 106 at each side of the semiconductor layer 104 symmetrically. Afterward, the third photoresist layer is removed.

In step S16, a passivation layer is formed.

A passivation layer is disposed on the source 105, the drain 106, and the gate insulating layer 103. A fourth photoresist layer is deposited on the passivation layer.

A fourth photo-mask process is described as follows.

In step S17, a pattern passivation layer is formed.

A fourth photo-mask is arranged above the fourth photoresist layer. An ultraviolet (UV) ray light source is used for developing the fourth photoresist layer with the fourth photo-mask to form a desired pattern on the passivation layer, and then, the passivation layer is etched to form the passivation layer 107. Afterward, the fourth photoresist layer is removed.

In step S18, a transparent conductive layer is formed.

A transparent conductive layer is disposed on the passivation layer 107. A fifth photoresist layer is deposited on the passivation layer 107.

A fifth photo-mask process is described as follows.

In step S19, a pixel electrode is formed.

A fifth photo-mask is arranged above the fifth photoresist layer. An ultraviolet (UV) ray light source is used for developing the fifth photoresist layer with the fifth photo-mask to form a desired pattern on the transparent conductive layer, and then, the transparent conductive layer is etched to form the pixel electrode 108. Afterward, the fifth photoresist layer is removed.

Nevertheless, the fabricating process above-described requires five photo-masks; therefore, the process is complicated.

Accordingly, what is needed is a thin film transistor substrate of a liquid crystal display configured to overcome the above-described problems.

### SUMMARY

An exemplary thin film transistor substrate includes a substrate, a gate, a gate insulating layer, an amorphous silicon layer, a pixel electrode, a drain, and a source. The gate is formed at the gate. The gate insulating layer is formed at the gate. The amorphous silicon layer is formed at the gate insulating layer. The transparent conductive layer is formed at the amorphous silicon layer. The pixel electrode is formed at the amorphous silicon layer. The drain is formed at the pixel electrode. The source is formed at the transparent conductive layer.

Other advantages and novel features will become more apparent from the following detailed description when taken in conjunction with the accompanying drawings.

### BRIEF DESCRIPTION OF THE DRAWINGS

In the drawings, all the views are schematic.

FIG. 1 is a cross-sectional view of a thin film transistor substrate in accordance with a preferred embodiment of the present invention.

FIG. 2 is a flow chart of steps of fabricating a thin film transistor substrate by three photo-mask process in accordance with a preferred embodiment of the present invention.

FIG. 3 is a cross-sectional view showing a fist metal layer, and a first photoresist layer formed at the substrate

FIG. 4 is a cross-sectional view showing a gate and a storage electrode formed on the substrate

FIG. 5 is a cross-sectional view showing a gate insulating layer, an amorphous silicon layer, and a doped amorphous silicon layer formed at the substrate.

FIG. 6 is a cross-sectional view showing a patterned amorphous silicon layer and a patterned doped amorphous silicon layer formed at the substrate

FIG. 7 is a cross-sectional view showing a conductive metal layer, and a second metal layer formed at the substrate.

FIG. 8 is a cross-sectional view showing a third photoresist layer and a third photo-mask

FIG. 9 is a patterned third photoresist layer.

FIG. 10 is a cross-sectional view showing a patterned second metal layer, patterned conductive metal layer, and a patterned doped amorphous silicon layer.

FIG. 11 is a cross-sectional view of a patterned third photoresist.

FIG. 12 is a cross-sectional view of a passivation layer formed at the substrate.

FIG. 13 is a cross-sectional view of a part of a conventional thin film transistor substrate of a liquid crystal display.

FIG. 14 is a flow chart of steps of fabricating a thin film transistor substrate.

### DETAILED DESCRIPTION OF PREFERRED EMBODIMENTS

Referring to FIG. 1, this shows a cross-sectional view of a thin film transistor substrate 200 in accordance with a preferred embodiment of the present invention. The thin film transistor substrate 200 includes a substrate 201, a gate 212, a storage electrode 213, a gate insulating layer 203, an amorphous silicon layer 214, a doped amorphous silicon layer 215, drain 217, a source 218, a pixel electrode 216, a transparent conductive layer 226, and a passivation layer 209.

The gate 212 and the storage electrode 213 are formed on the substrate 201. The gate insulating layer 203 is formed on the gate 212, the storage electrode 213, and the substrate 201. The amorphous silicon layer 214 is disposed on the gate insulating layer 203 above the gate 212 and the doped amorphous silicon layer 215 is formed thereon. The transparent conductive layer 226 and the pixel electrode 216 are formed at the gate insulating layer 203 symmetrically. The source 217 is formed on the conductive layer 226, and the drain 218 is formed on the pixel electrode 216 symmetrically. The passivation layer 209 is formed on the gate insulating layer 204, the source 217, the drain 218, the pixel electrode 216, and the doped amorphous silicon layer 215.

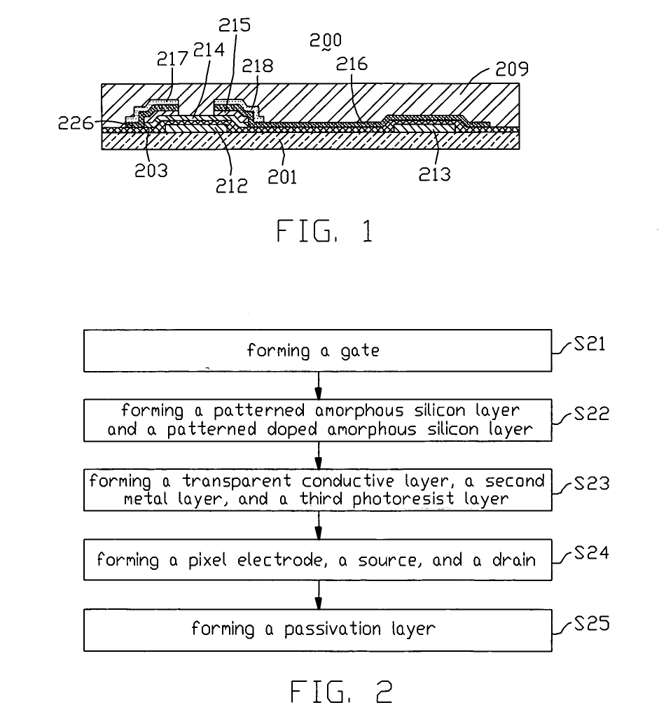

Referring to FIG. 2, this shows a flow chart of steps of fabricating a thin film transistor substrate 200 by three photo-mask in accordance with a preferred embodiment of the present invention.

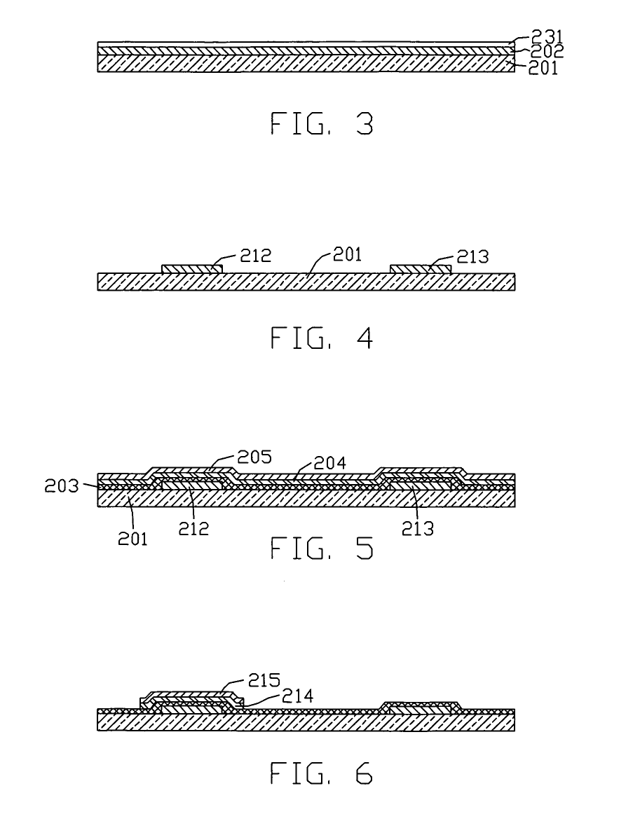

Referring to FIG. 3, this shows a cross-sectional view showing a fist metal layer, and a first photoresist layer formed at the substrate.

A first photo-mask process is described as follows.

In step S20, a gate is formed.

The substrate 201 made from insulating material, such as, glass, quartz or porcelain, is provided. A first metal layer 202 made from aluminum, molybdenum, chromium, tantalum, or copper, is deposited on the substrate 201, and than, a first photoresist layer 231 is deposited on the first metal layer 202.

Referring to FIG. 4, this shows a cross-sectional view showing a gate and a storage electrode formed on the substrate. A first photo-mask is arranged above the first photoresist layer 231. An ultraviolet (UV) ray light source is used for developing the first photoresist layer 231 with the first photo-mask to form a desired pattern for a gate, and a desired pattern for a storage electrode, and then, the first metal layer 202 is etched to form the gate 212 and the storage electrode 213. Afterward, the first photoresist layer 231 is removed.

A second photo-mask process is described as follows.

In step S21, a gate insulating layer, an amorphous silicon layer and a doped amorphous silicon layer are formed at the substrate.

Referring to FIG. 5, this shows a cross-sectional view showing a gate insulating layer, an amorphous silicon layer, and a doped amorphous silicon layer formed sequentially at the substrate. The gate insulating layer 203 is formed by chemical vapor deposition using silicon nitride with a reaction gas, such as, SiH4, NH3 on the substrate 201, the gate 202, and the storage electrode 213. Then, an amorphous silicon layer 204 is formed by chemical vapor deposition on the gate insulating layer 302. The amorphous silicon layer 204 is doped with impurity ions forming a doped amorphous silicon layer 205.

In step S22, a patterned amorphous silicon layer and a patterned doped amorphous silicon layer are formed at the substrate.

Referring to FIG. 6, this shows a cross-sectional view showing a patterned amorphous silicon layer and a patterned doped amorphous silicon layer formed at the substrate. A second photoresist is deposited on the doped amorphous silicon layer 205, and then, a second photo-mask is arranged above the second photoresist layer. An ultraviolet (UV) ray light source is used for developing the second photoresist layer with the second photo-mask to form a desired pattern on the doped amorphous silicon layer 204 and a doped amorphous silicon layer 205, and then, the amorphous silicon layer 204 and the doped amorphous silicon layer 205 is etched to form the desired patterned amorphous silicon layer 214 and a the desired patterned doped amorphous silicon layer 215. Afterward, the second photoresist layer is removed.

In step S23, a transparent conductive layer, a second metal layer, and a third photoresist layer are formed at the substrate.

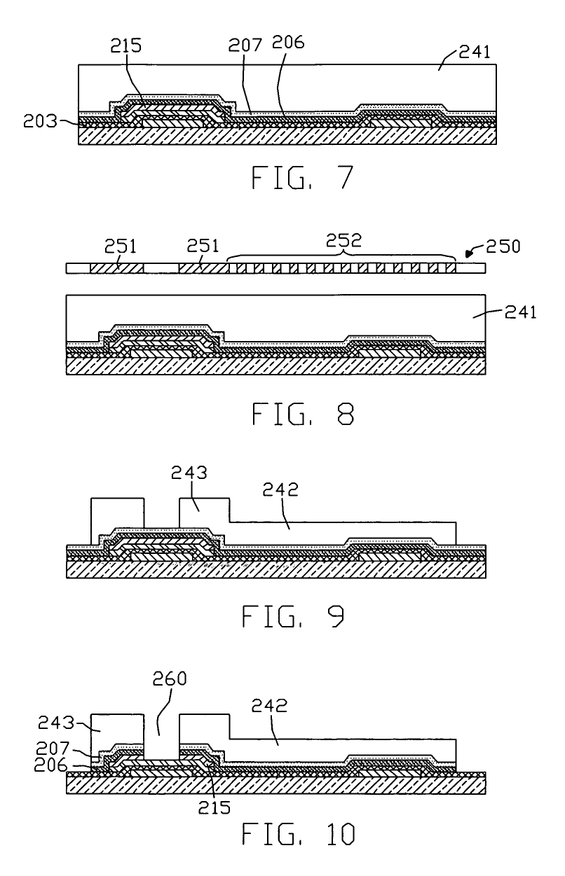

Referring to FIG. 7, this shows cross-sectional view showing a conductive metal layer, and a second metal layer formed at the substrate sequentially. The conductive metal layer 206 made from indium tin oxide (ITO) or indium zinc oxide (IZO), is deposited on the doped amorphous silicon layer 215. The second metal layer 207 made from aluminum, aluminum alloy, molybdenum, chromium, tantalum, or copper, is deposited on the conductive metal layer 206. A third photoresist layer 241 is deposited on the second metal layer 207.

A third photo-mask process is described as follows.

In step S24, a pixel electrode, a source, and a drain are formed at the substrate.

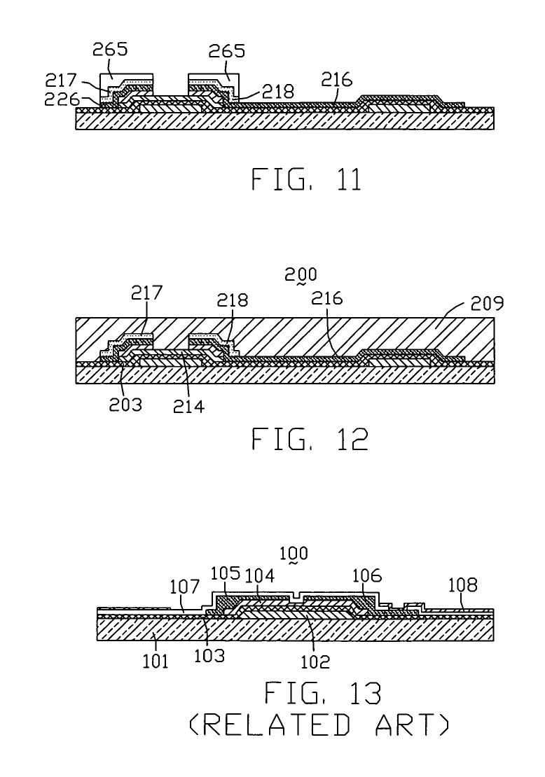

Referring to FIG. 8, this shows a cross-sectional view showing a third photoresist layer and a third photo-mask. The third photo-mask 250 includes a plurality of light-blocking regions 251, and a slit region 252 having a plurality of slits (not labeled). An ultraviolet (UV) ray light source is used for developing the third photoresist layer 241 with the third photo-mask 250 to form a desired pattern for the third photoresist layer shown in FIG. 9.

Referring to FIG. 9, this shows a cross-sectional view showing a pattern third photoresist layer. Because of different exposure between the slit region 252 and other region having light-blocking regions 251; therefore, resulting a thin photoresist layer 242, and a thick photoresist layer 243 which a profile thereof is thicker than a profile of the thin photoresist layer 242.

Referring to FIG. 10, this shows a cross-sectional view showing a pattern second metal layer, pattern conductive metal layer, and a pattern doped amorphous silicon layer. Part of the conductive metal layer 206, second metal layer 207, and doped amorphous silicon layer 215 is etched out forming a conductive metal layer 206, a pattern second metal layer 207, and an opening 260.

Referring to FIG. 11, this shows a cross-sectional view showing a pattern third photoresist. The thin and thick photoresist layer 242, 243 are etched. The etching process is controlled to remove the thin photoresist layer 242, and a thin profile of the thick photoresist layer 243 is remained two pattern photoresist layers 265 forming a pixel electrode 216 and a transparent conductive layer 226.

In step S25, a passivation layer is formed at the substrate.

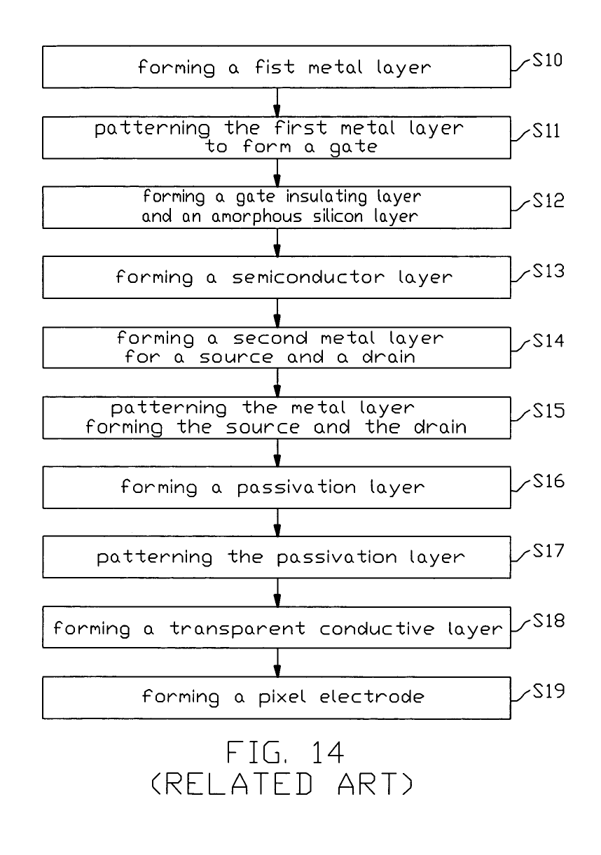

Referring to FIG. 12, this shows a cross-sectional view showing a passivation layer formed at the substrate. Firstly, the pattern third photoresist layers 265 are removed. The passivation layer 209 is deposited on the gate insulating layer, the source 217, the drain 218, the pixel electrode 216, and the amorphous 214.

The process of fabricating the pixel electrode 216, the source 217, and the drain 218 is finished by one photo-mask process, therefore, the complication of fabrication the thin film transistor substrate and the cost thereof can be reduced.

While preferred and exemplary embodiments have been described above, it is to be understood that the invention is not limited thereto. To the contrary, the above description is intended to cover various modifications and similar arrangements as would be apparent to those skilled in the art. Therefore, the scope of the appended claims should be accorded the broadest interpretation so as to encompass all such modifications and similar arrangement.

What is claimed is:

1. A thin film transistor substrate, comprising:
a substrate;
a gate formed at the substrate;
a gate insulating layer formed at the gate;
an amorphous silicon layer formed at the gate insulating layer;
a transparent conductive layer formed at the amorphous silicon layer;
a pixel electrode formed at the amorphous silicon layer;
a drain formed at the pixel electrode; and
a source formed at the transparent conductive layer.

2. The thin film transistor substrate as claimed in claim 1, wherein a doped amorphous silicon layer is formed in the amorphous silicon layer.

3. The thin film transistor substrate as claimed in claim 1, further comprising a passivation layer formed at the source, the drain, the pixel electrode, and the amorphous silicon layer.

4. The thin film transistor substrate as claimed in claim 1, further comprising a storage electrode formed at the substrate.

5. The thin film transistor substrate as claimed in claim 1, wherein the pixel electrode is made from indium tin oxide or indium zinc oxide.

6. The thin film transistor substrate as claimed in claim 1, wherein the transparent conductive layer is made from indium tin oxide or indium zinc oxide.

7. The thin film transistor substrate as claimed in claim 1, further comprising a storage line formed at the substrate.

8. The thin film transistor substrate as claimed in claim 1, further comprising an amorphous silicon layer formed in the amorphous silicon layer by doping impurity ions.

9. A method for fabricating a thin film transistor substrate, comprising steps of:
providing a substrate;
forming a first metal layer at the substrate;
forming a fist photoresist on the first metal layer;
developing the fist photoresist layer to form a patterned first photoresist layer;
etching potions of the first metal layer not covered by the patterned photoresist to form a gate;
forming a gate insulating layer at the gate and the substrate;
forming an amorphous silicon layer at the gate insulating;
forming a second photoresist on the amorphous silicon layer;
developing the second photoresist layer to form a patterned second photoresist layer;
etching potions of the amorphous silicon layer not covered by the patterned photoresist;
forming a transparent conductive layer on the amorphous silicon layer;
forming a second metal layer on the transparent conductive layer;
forming a third photoresist layer on the transparent conductive layer and the second metal layer;
developing the third photoresist layer to form a pattern third photoresist layer; and
etching potions of the transparent conductive layer to form a source, a drain, and a pixel electrode.

10. The method for fabricating a thin film transistor substrate as claimed in claim 9, wherein the third photoresist layer is developed by a photo-mask including a plurality of slits.

11. The method for fabricating a thin film transistor substrate as claimed in claim 9, wherein a passivation layer is formed at the source, the drain, the amorphous silicon layer and the pixel electrode.

12. The method for fabricating a thin film transistor substrate as claimed in claim 9, wherein the third photoresist layer comprises a thick photoresist layer, and a thin photoresist layer, and a profile of the thick photoresist layer is thicker than a profile of the thin photoresist layer.

13. The method for fabricating a thin film transistor substrate as claimed in claim 9, wherein the pixel electrode is made from indium tin oxide or indium zinc oxide.

14. The method for fabricating a thin film transistor substrate as claimed in claim 9, wherein the transparent conductive layer is made from indium tin oxide or indium zinc oxide.

15. The method for fabricating a thin film transistor substrate as claimed in claim 9, further comprising an amorphous silicon layer formed in the amorphous silicon layer by doping impurity ions.

16. The method for fabricating a thin film transistor substrate as claimed in claim 9, further comprising a storage line formed at the substrate.

17. A thin film transistor substrate comprising:
a substrate;
a gate formed at the substrate;
a gate insulating layer formed at the gate;
an amorphous silicon layer formed at the gate insulating layer;
a first conductive metal layer including a raised section which is applied upon the amorphous silicon layer including two opposite ends in a lateral direction;
a second metal layer including a raised region applied upon the first metal layer including two opposite raised section of the first conductive metal layer;
a cutout vertically extending through all the raised region of the second metal layer, the raised section of the first conductive metal layer, and the amorphous silicon layer under the raised section of the first conductive metal layer; and
a passivation layer applied upon the raised region of the second metal layer; wherein
the passivation layer invades and fills the cutout.
